(19) United States
(12) Patent Application Publication
(10) Pub. No.: US 2008/0170457 A1
(43) Pub. Date: Jul. 17, 2008

(54) METHOD FOR SENSING A SIGNAL IN AN INTEGRATED CIRCUIT COMPLEMENTARY FUSE ARRANGEMENT

(75) Inventor: Chandrasekharan Kothandaraman, Hopewell Junction, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/622,614

(22) Filed: Jan. 12, 2007

(51) Int. Cl. H03K 17/18

(52) U.S. Cl. 365/225.7; 327/525

(57) ABSTRACT

A method for sensing an electrical signal includes the steps of: providing an arrangement having a fuse connected in series to an antifuse, the arrangement further having an output tap connected to an intermediate node located between the fuse and the antifuse; programming the fuse and the antifuse; applying a sense signal across the combination of the programmed fuse and the programmed antifuse, and then measuring an output signal at the output tap.

### BACKGROUND OF THE INVENTION

1. Technical Field of the Invention

The invention relates generally to the field of digital electronic circuits and, more specifically, to the field of integrated semiconductor circuits (ICs).

2. Description of Related Art

In electronic devices including integrated circuits, it is often desirable to be able to store information permanently, or to form permanent connections on the integrated circuit after it is manufactured. There are multiple ways to achieve this storage of information, the most common ones being a fuse, an anti-fuse or a nonvolatile memory element including arrays of floating gate transistors.

Fuses or devices forming fusible links have been used for this purpose since the earliest days of electrical and electronic circuitry. Originally, they were used to limit the flow of current that would cause damage to machinery, but have been adopted in integrated circuits to invoke redundant elements to replace identical defective elements. Further, fuses can be used to store important security information such as cryptographic keys, or to adjust the speed of a circuit by adjusting the resistance of the current path.

Typically, fuses involve a thin strip of conductor that is programmed or ‘blown’ by the application of an electrical current of a certain magnitude or the application of laser energy. These types of fuses change their resistance by several orders of magnitude-typically, going from few ohms to several megohms. The change in the resistance of these fuses is sensed using appropriate conventional electronic circuitry and its value can be stored as a binary digit, say, for instance, the lower resistance or voltage representing a ‘0’ and the higher resistance or voltage representing a ‘1’.

An example of this type of fuse device 30, illustrated in plan view in FIG. 1A and in cross-sectional view in FIG. 1B through line A-A′, and in cross-sectional view in FIG. 1C through line B-B′, is based on a rupture, agglomeration or electromigration of silicided polysilicon. These types of fuses include a silicide layer 20 disposed on a polysilicon layer 18, overlain by a layer of silicon nitride 24. Electrical contacts 25 are coupled to the silicide layer 20 in a pair of contact regions 22 on either side of a fuse element 27, to provide an electrical connection between the fuse and external components for programming and sensing. FIG. 1A illustrates a top view of the typical shape, and includes the fuse element 27 and contact regions 22. Conventional sensing or measuring circuitry SC is also shown. FIG. 1B shows a side view of a typical fuse construction in which the polysilicon layer 18 and the silicide layer 20 are provided at a uniform thickness disposed on an oxide layer 10 also of a uniform thickness. FIG. 1C illustrates a cross-section through the fuse link region 27. Generally, a blanket nitride capping layer 24 is also provided over the layers 20, 22.

The silicide layer 20 has a first resistance and the polysilicon layer 18 has a second resistance which is greater than the first resistance. In an intact condition, the fuse link has a resistance determined by the resistance of the silicide layer 20. In typical applications, when a programming potential (voltage) is applied, providing a requisite current and voltage over time, across the fuse element 27 via the contact regions 22, the silicide layer 20 begins to randomly “ball-up” eventually causing an electrical discontinuity, rupture or break in some part of the silicide layer 20. Thus, the fuse link 27 has a resultant resistance determined by that of the polysilicon layer 18 (i.e. the programmed fuse resistance is increased to that of the second resistance). This type of a fuse in the unprogrammed state can have resistance ranging from 50 ohms to 150 ohms. The final programmed resistance can reach 1 megohms. A typical sensing circuitry SC (shown schematically in FIG. 1A) would apply a voltage corresponding to 1V across the fuse, i.e. across the contacts 25 as shown. In the un-programmed state, this voltage application would result in the fuse drawing up to 2 mA of current and this will make the sense circuitry record a ‘0’, while in the programmed state it will draw only microamps of current resulting in a ‘1’.

See also, for example, U.S. Pat. No. 6,624,499 B2, SYSTEM FOR PROGRAMMING FUSE STRUCTURE BY ELECTROMIGRATION OF SILICIDE ENHANCED BY CREATING TEMPERATURE GRADIENT, issued Sep. 23, 2003, by Kothandaraman et al., and “Electrically Programmable Fuse (eFuse) Using Electromigration in Silicides”, by Kothandaraman et al., IEEE Electron Device Letters, Vol. 23, No. 9, September 2002, pp. 523-525, which are both incorporated in their entireties herein by reference.

An alternate or ‘complementary’ way to realize this resistance change function is via an antifuse, typically made like a capacitor, with two metallic layers separated by an insulator. In the un-programmed state, the antifuse has a high resistance, as the insulator inserted in between the two conductors prevents any flow of current between the two conductors. The application of a suitable ‘programming’ voltage to the two metallic layers causes the breakdown of the insulator resulting in the creation of a conductive path between the two conductors. Thus, the resistance of the antifuse is decreased upon programming, typically going from several hundreds of megohms down to kilo-ohms. Similarly to the fuse, the antifuse can also be used with appropriate circuitry to represent a ‘0’ or a ‘1’ in digital systems.

An example of a conventional antifuse is shown in top plan view in FIG. 2A and a corresponding cross-sectional view along A-A′ is shown in FIG. 2B. A substrate 220 is made from a typical semiconductor material such as silicon and is made conductive via suitable doping. A thin insulating layer 210 is grown or deposited on the substrate 220. The insulating layer 210 is typically silicon dioxide and has a thickness ranging from approximately (±10%) 8 nm to approximately 40 nm. On top of this layer 210, a conductor 200, typically doped polysilicon followed by a silicide, is deposited. The top conductor 200 is patterned to a desired shape as shown in FIG. 2A. Then, contacts 230, 240 are formed to both the top conductor (200) and to the bottom substrate (220). The initial resistance between contacts 230, 240 is typically very large, in excess of 1 megohm, typically reaching 100 megohm. The programming is achieved by applying a fairly high voltage, dependent on the thickness of insulator 210, between the two contacts 230, 240. Of course, contacts 230, 240 may represent sets (pluralities) of contacts, as appropriate. This voltage application results in the break-down of the insulator 210 and further results in the formation of conducting filaments through insulator 210. This decreases the resistance between the two contacts 230, 240 to about 1 kilo-ohm. Typical sensing circuitry would apply a voltage corresponding to about 1V across the antifuse. In the un-programmed state, this would result in the antifuse's drawing only a maximum of a micro-amp of current and this will make the sense circuitry record a ‘0’, while in the programmed state the antifuse will draw up to 1 mA of current resulting in or corresponding to, for example, a ‘1’.

Another way to realize the permanent storage of information is via the use of non-volatile memory elements where the change in the threshold voltage of a floating gate transistor is used to store information permanently. However, this approach involves the use of specialized expensive on-chip processes that are not typically available in most semiconductor chips. Moreover, floating gate transistor technology has not scaled in the same way or to the same degree as the other storage and logic element technologies. Thus, semiconductor chips such as microprocessors and memory chips often do not have any non-volatile memory via the use of floating gate transistors, but instead rely on arrays of fuses or antifuses.

With the steady increase in the density complexity and speed of operations of the integrated chips, there is an increasing need to integrate larger numbers of fuses and anti-fuses and have the information read or sensed faster. Typically, this number has already exceeded 100 Kbits, with each subsequent generation doubling the number of these elements. With traditional fuses and antifuses, although the area needed on the chip has continued to decrease, the current needed to read or sense the fuse has not decreased at the same pace. In the present inventor's opinion, this has resulted in a situation where the need for relatively large read currents has posed a problem—inability to read the elements very fast; indeed, various delay elements have to be specially created to achieve this read function resulting in more complexity and reduced speed.

Arrangements including combinations of fuses and antifuses are also known. See, for example, U.S. Pat. No. 5,903,041, INTEGRATED TWO-TERMINAL FUSE-ANTIFUSE AND FUSE AND INTEGRATED TWO-TERMINAL FUSE-ANTIFUSE STRUCTURES INCORPORATING AN AIR GAP, by Fleur et al., issued May 11, 1999, and U.S. Pat. No. 5,412,593, by Magel et al., issued May 2, 1995, FUSE AND ANTIFUSE REPROGRAMMABLE LINK FOR INTEGRATED CIRCUITS, both of which patent are incorporated herein in their entireties. In FIGS. 2A-2C of Patent '593, a fuse-antifuse link 10, nodes T₁, T₂ center node T_{P}, antifuse 16 and fuse 12 are shown. From the top down shown in those figures; initial state, after first programming and after second programming. First programming applies a suitable voltage across T_{P} and T₁, and second programming applies a suitable voltage across T_{P} and T₂. However, the present inventors believe that the center node T_{P} is used by Patent '593 for programming the line 10, and not for sensing or measuring a signal between T_{P} and either T₁ or T₂.

Therefore, the present inventor believes it is very desirable to develop methods and apparatus for sensing voltages in IC complementary fuse arrangements that will not require significant amounts of current for reading information, while providing a reliable way to store the information permanently.

It is a principal object of the present invention to provide a method for sensing signals (e.g. voltages) in complementary fuse arrangements that require low amounts of current for reading, while reliably and permanently storing information.

It is a further object of the present invention to provide a method for measuring voltages or resistances in integrated circuit complementary fuse arrangements by employing conventional sensing/measuring circuitry, but which circuiting occupies less area of the semiconductor substrate (e.g. silicon) because minimal current is drawn through the circuitry.

It is an additional object of the present invention to provide arrangements for accomplishing the inventive methods.

### SUMMARY OF THE INVENTION

According to the embodiment of the present invention, a method for sensing an electrical signal (such as a voltage) includes: providing an arrangement including a fuse connected in series to an antifuse, the arrangement further including an output tap connected to an intermediate node connected between the fuse and the antifuse, programming the fuse and the antifuse, applying a sense signal (such as a suitable voltage) across the combination of the programmed fuse and the programmed antifuse, and then measuring an output signal (e.g. voltage) at the output tap. The arrangement is programmed by the application of a voltage to the two terminals of the fuse and to the two terminals of the antifuse, in either order. The programmed fuse increases in resistance from approximately (±10%) 100 ohms to approximately one (1) megaohm, while the programmed anti-fuse decreases in resistance from approximately 100 mega ohms to less than approximately one (1) kilo-ohm.

The state of the arrangement, whether programmed or not, is detected by applying a voltage, typically 1 volt, across the entire arrangement, and then measuring the voltage at the output tap connected to the intermediate node. This voltage changes from a large voltage (e.g., approximately full applied voltage—e.g., approximately one volt) in the unprogrammed state, to a small value, e.g., microvolts, in the programmed state.

Another broad embodiment of the method according to the present invention includes measuring an output signal at an output tap connected to a node located between a programmed fuse and a programmed antifuse formed as an integrated circuit.

The present invention has the advantage that the output voltage swings from 1V in the unprogrammed state to microvolts in the programmed state, but without ever drawing significant current. The inventive method and arrangement draw, for example, less than one microamp during the sensing or measuring step. This enables easy integration of a large number of these devices (fuse and antifuse) allowing for more complex chip functions. This also allows for reading a large number of these elements simultaneously.

### BRIEF DESCRIPTION OF THE DRAWINGS

For a more complete understanding of the present invention, reference is made to the following detailed description taken in conjunction with the accompanying drawings, which are not necessarily drawn to scale, wherein:

FIG. 1A illustrates a plan view of a conventional fuse or eFuse formed as an IC;

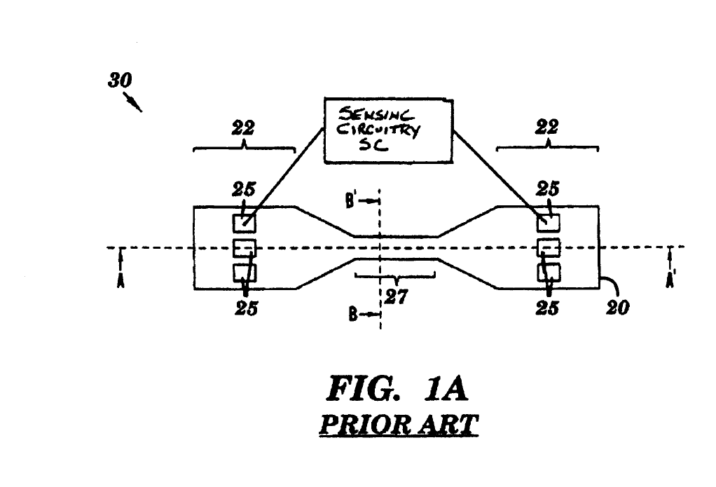

FIG. 1B illustrates a cross-sectional view of the conventional fuse through A-A′;

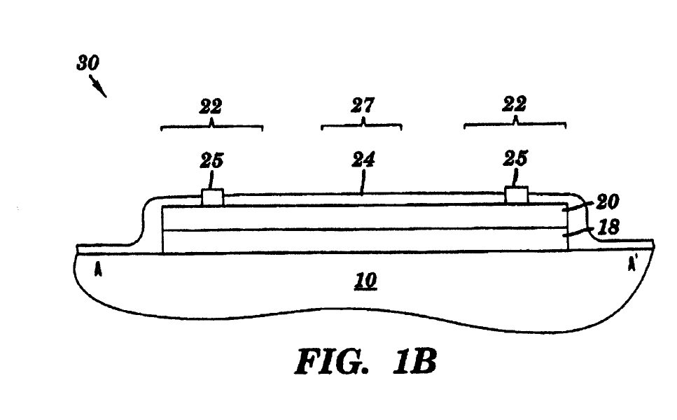

FIG. 1C illustrates a cross-sectional view of the conventional fuse through B-B′;

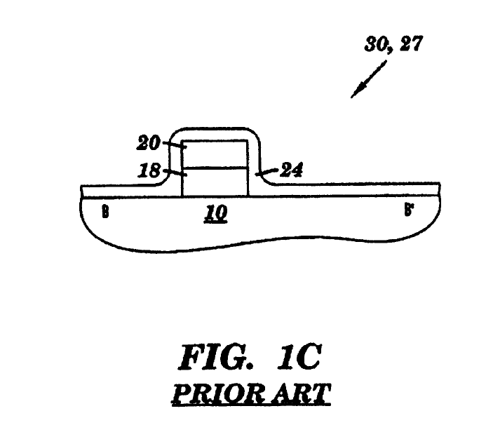

FIG. 2A illustrates a plan view of a conventional antifuse formed as an IC;

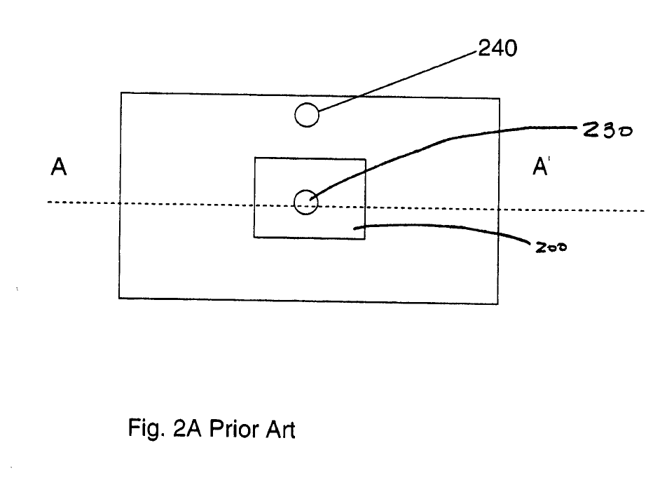

FIG. 2B illustrates a cross-sectional view of the conventional antifuse;

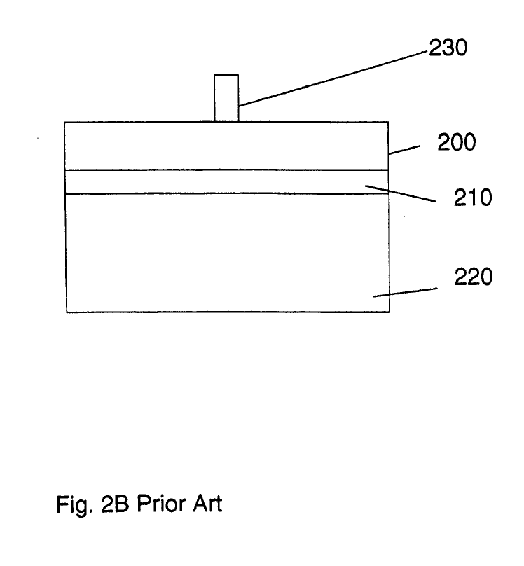

FIG. 3A illustrates a top plan view of a device arrangement (fuse and antifuse) useful for practicing a method of the present invention;

FIG. 3B illustrates a cross-sectional view through A-A′ of the arrangement of FIG. 3A, in an unprogrammed state;

FIG. 3C illustrates a schematic circuit diagram of the device arrangement shown in FIG. 3A and FIG. 3B, connected to voltage sensing circuits, in an unprogrammed state;

FIG. 3D illustrates a schematic circuit diagram of the device arrangement shown in FIG. 3A and FIG. 3B, connected to voltage sensing circuits, in a programmed state;

FIG. 4A illustrates a plan view of the an alternate embodiment of the device arrangement;

FIG. 4B illustrates a cross-section through A-A′ of the device arrangement of FIG. 4A;

FIG. 4C illustrates a schematic diagram circuit of the device arrangement shown in FIG. 4A and FIG. 4B, connected to voltage sensing circuits, in an unprogrammed state;

FIG. 4D illustrates a schematic circuit diagram of the device arrangement shown in FIG. 4A and FIG. 4B, connected to voltage sensing circuits, in a programmed state;

FIGS. 5A-E illustrate cross-sections sequential intermediate structures for forming a complimentary fuse arrangement useful for practicing the method of the present invention;

FIG. 6 is a chart showing the electrical characteristics of the devices when unprogrammed and programmed voltages are measured at an output tap connected to an intermediate node according to the method of the present invention;

FIG. 7 is a flow chart showing an embodiment of the method according to the present invention.

### DETAILED DESCRIPTION

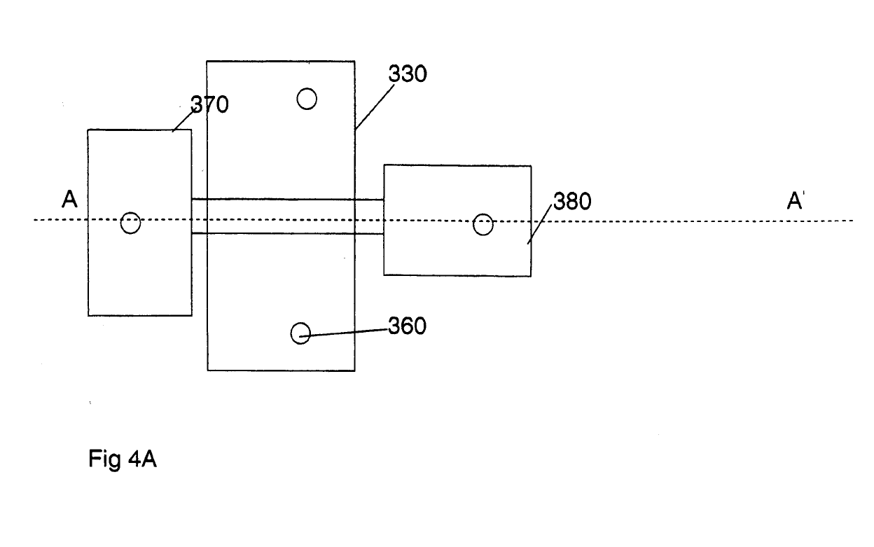

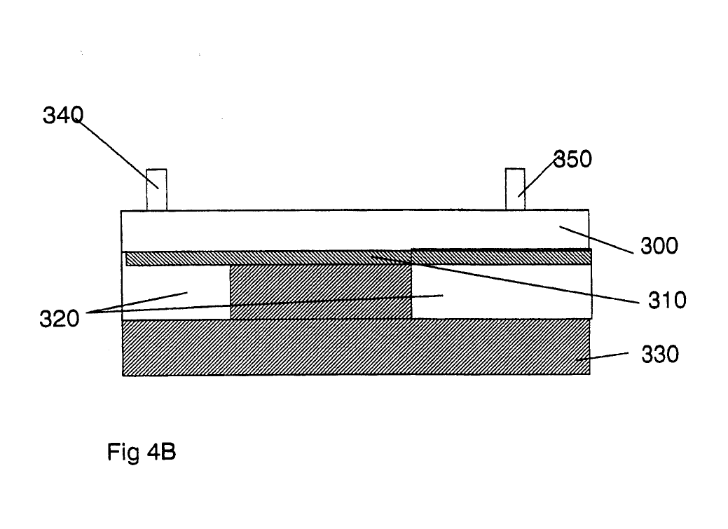

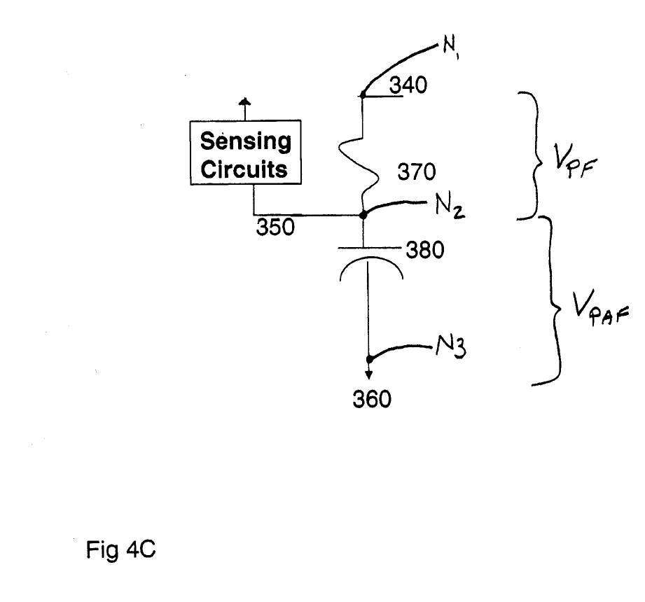

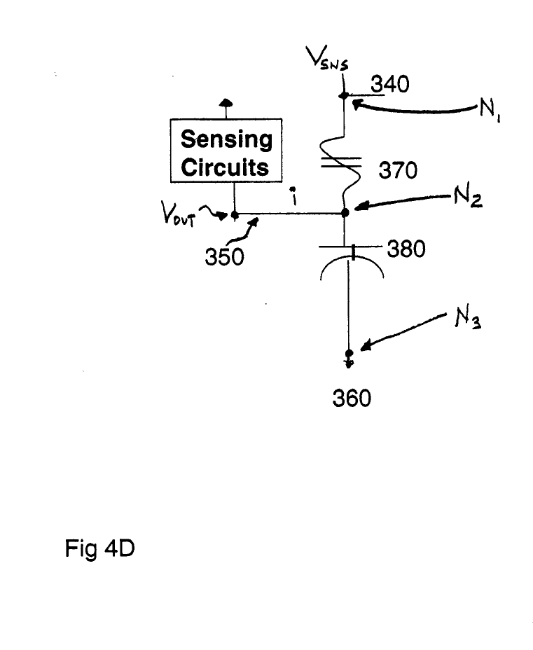

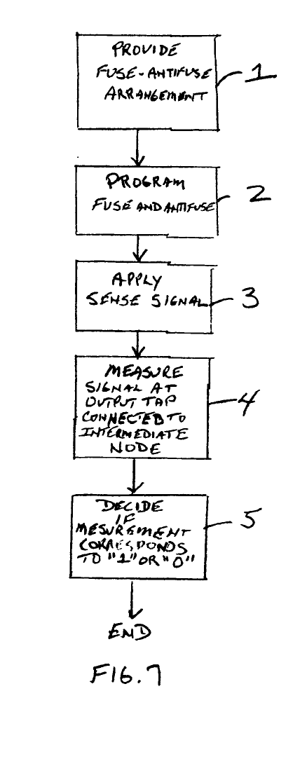

According to the embodiment of the present invention, as shown for example in the flow diagram of FIG. 7, a method for sensing an electrical signal (such as a voltage) includes: providing an arrangement (e.g. FIG. 4C) which includes a fuse 370 connected in series to an antifuse 380. The arrangement further includes an output tap 350 connected to an intermediate node N₂ connected between the fuse and the antifuse. The following steps are then performed: programming the fuse and the antifuse, applying a sense signal (such as a suitable voltage V_{SNS}) across the combination of the programmed fuse and the programmed antifuse (see, e.g., FIG. 4D), and then measuring an output signal (e.g. voltage V_{OUT}) at the output tap 350. The arrangement is programmed by the application of a suitable programming voltage to or across the two terminals 340, 350 of the fuse and a suitable programming voltage to or across the two terminals 350, 360 of the antifuse, in either order. The programmed fuse (370, FIG. 4D) increases in resistance from approximately (±10%) 100 ohms to approximately one (1) megohm, while the programmed antifuse (380, FIG. 4D) decreases in resistance from approximately 100 megohms to less than approximately one (1) kilo-ohm.

The state of the arrangement, whether programmed or not, is detected by applying a voltage V_{SNS}, typically 1 volt, across the entire arrangement (e.g. across contacts 340, 360), and then measuring the voltage V_{OUT} at the output tap 350 connected to the intermediate node N₂. This voltage V_{OUT} changes from a large voltage (approximately full applied voltage—e.g., approximately one volt) in the unprogrammed state, to a small value (e.g., microvolts) in the programmed state.

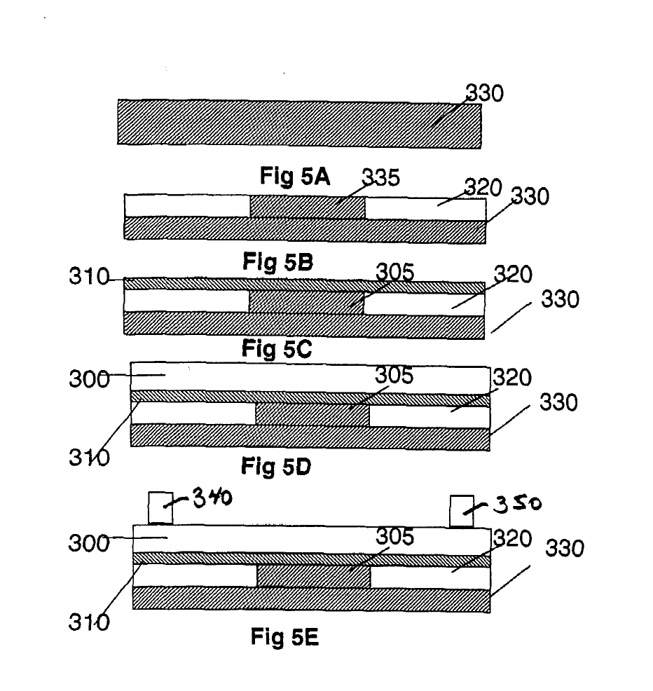

One complementary fuse arrangement useful for practicing the embodiment (FIG. 7) of a method according to the present invention is shown and described with references to FIGS. 4A, 4B, 4C and 4D. FIGS. 5A-5E show side sectional schematic views of sequential intermediate structures and the final structure for making the fuse and antifuse structural arrangement (unprogrammed) shown in FIG. 4A and FIG. 4B.

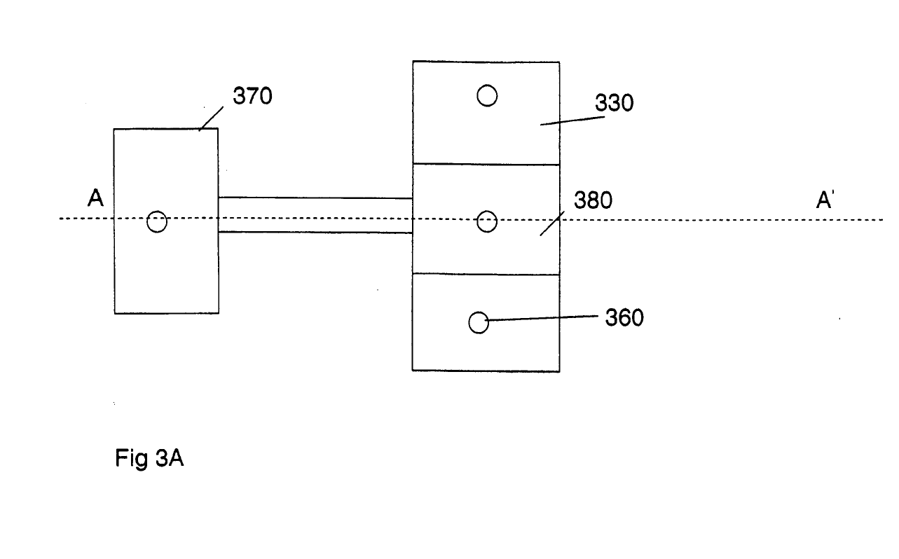

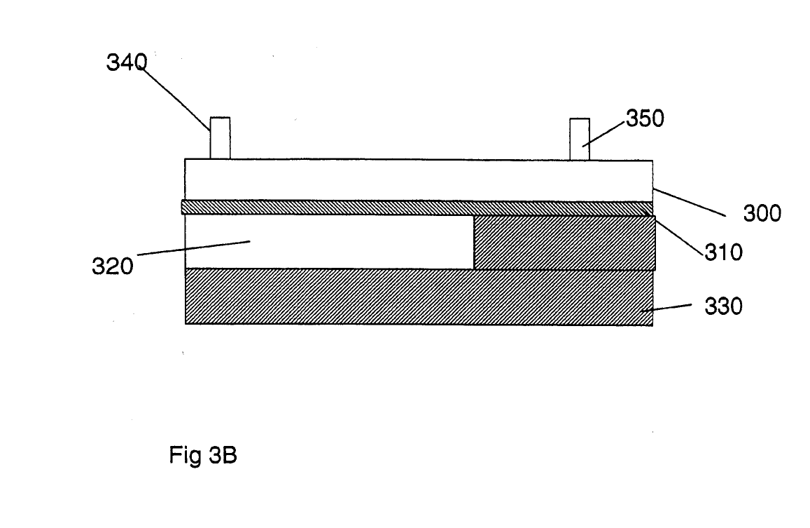

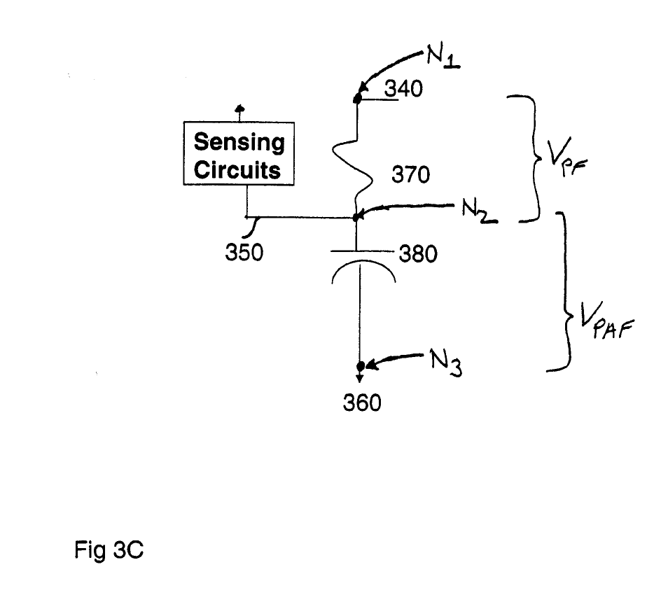

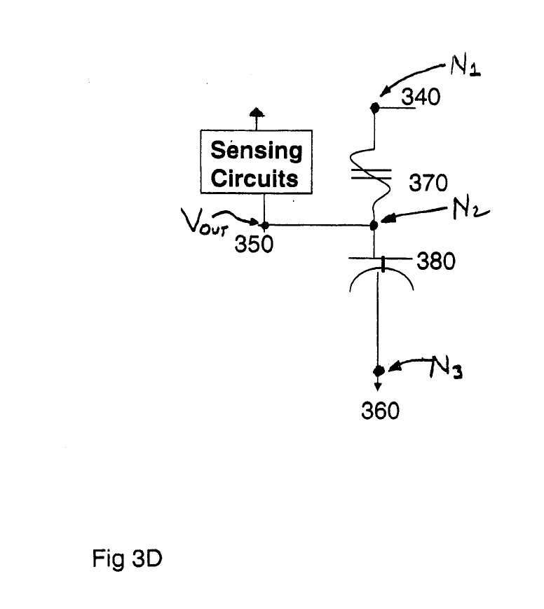

Another fuse-antifuse structural arrangement useful for practicing an embodiment of a method according to an embodiment of the present invention is shown and described with reference to FIGS. 3A, 3B, 3C and 3D.

One embodiment of a method according to the present invention is shown by steps listed in the flow diagram of FIG. 7. As shown in FIG. 7, Step one (1): provide a fuse and antifuse arrangement, such as an arrangement shown in either FIG. 4A or FIG. 3A, including a fuse 370 serially connected to an antifuse 380. In a Step 2: program the fuse 370 and the antifuse 380, in either order by application of a suitable voltage or suitable voltages. The fuse 370 is programmed by applying a suitable voltage V_{PF} (e.g. approximately one to approximately three volts, shown schematically in FIG. 3C and FIG. 4C) across an end node N₁ (or contact 340 connected to the node N₁) and an intermediate node N₂ (or contact 350 connected to the node N₂). See FIG. 3C. The suitable voltage is applied by any suitable source of electrical potential (not shown). The antifuse is programmed by applying a suitable voltage V_{PAF} (e.g., approximately two to approximately five volts) across an end node N₃ and the intermediate node N₂. Applying such voltages is accomplished in any conventional fashion or technique, such as those described in U.S. Pat. No. 5,412,593, previously incorporated herein. After the programming step 2, the states of fuse 370 and the antifuse 380 are shown schematically in FIGS. 3D and 4D.

Next, in step 3, apply a sense voltage V_{SNS} (e.g. one volt) across the end nodes N₁, N₃, and then in step 4 measure an output voltage V_{OUT} between the output tap 350 and ground or a suitable reference voltage. The sense voltage is applied and a voltage V_{OUT} is measured by means of any suitable sensing circuit connected to N₂, as shown in FIG. 3D or 4D. The sensed or measured voltage V_{OUT}=V_{antifuse}/V_{fuse}+V_{antifuse}. The measured voltage V_{OUT} is the voltage measured across antifuse divided by a sum of the voltages measured across the fuse and the antifuse.

Then, in step 5, decide if the sensed voltage corresponds to a digital “1”0 or “0”.

The voltage sensing circuits per se are conventional and include, for example, cross-coupled inverters that convert the voltage V_{OUT} to a digital value. The sensing circuits can also include a source of potential to apply the sense voltage V_{SNS} (e.g. one volt) to the node N₁. Alternatively, the sense voltage is applied by another suitable source of potential (FIG. 4D). According to the present invention, the current (i) flowing through the branch or output tap 350 is very small, for example, approximately one microamp or less. Thus, the arrangement draws minimal current and a multiplicity of fuse-antifuse arrangements and sensing circuits can be formed, the inventor believes, more cost effectively.

FIG. 3A shows a top plan schematic view and FIG. 3B a side sectional schematic view of a fuse-antifuse arrangement useful for practicing a method according to the present invention. Constructing fuse-antifuse arrangements, with or without sensing circuits and suitable voltage sources, for the present invention is well within the skill of the art, in view of the instant specification and drawing figures.

FIG. 3A shows a fuse 370, an antifuse 380, ground contacts 360, all formed on a semiconductor substrate 330, only part of which 330 is shown in FIG. 3A. The substrate 330 is for example bulk silicon, SOI or another suitable substrate.

FIG. 3B is a side sectional schematic view through the line A-A′ of FIG. 3A.

FIG. 3C is a circuit diagram showing schematically an arrangement for practicing the method according to the present invention. After the fuse 370 and the antifuse 380 are programmed (FIG. 3D), the voltage V_{OUT} is read or sensed by any conventional suitable sensing or measuring circuits. According to the present invention, such sensing is performed at an output tap 350 connected to an intermediate node N₂ as shown in FIG. 3D. The sensing (e.g., measuring) is performed relative to ground or some other suitable reference voltage.

FIGS. 4A-4B show various views of an alternative fuse-antifuse arrangement, while FIG. 5 shows various side sectional schematic views of structures for creating the arrangement of FIGS. 4A and 4B. FIG. 4C shows the arrangement before programming, while FIG. 4D shows the arrangement after programming but with the addition of V_{SNS} and the sensing circuits.

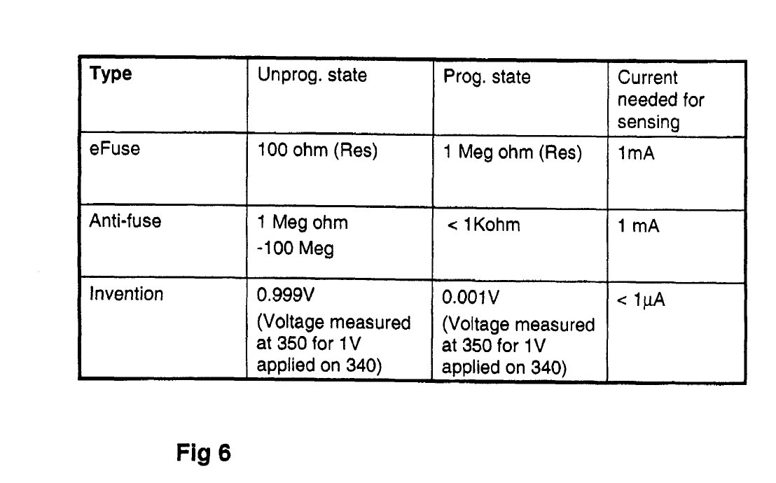

FIG. 6 shows various electrical characteristics of an arrangement for practicing an embodiment of the invention.

FIG. 7 is a flow diagram showing the steps 1-5 according to an embodiment of the invention.

Manufacture of a fuse-antifuse arrangement 4A or 3A is accomplished by well known IC manufacturing techniques and tools, and need not be discussed in great detail. The structure of FIG. 4A is constructed as follows with reference to FIGS. 5A-5E.

In FIG. 5A, a silicon wafer or substrate 330 is provided. Regions of active area 335 are patterned, and a remainder of area is filled with an isolation oxide 320. The intermediate structure is then planarized to result in the structure shown in FIG. 5B. Patterning is accomplished, e.g., by various masking and etching techniques, while planarizing is effected, e.g., by chemical mechanical planarization, all well known.

In FIG. 5C, a gate oxide 310 of a suitable thickness, typically ranging from approximately 8 nm to approximately 30 nm, is grown via a oxidation furnace or deposited via standard epitaxial techniques on the entire structure.

Next, a polysilicon layer 300 of a suitable thickness, typically ranging from approximately 500 nm to approximately 1500 nm, is deposited onto the entire structure of FIG. 5B, as shown in FIG. 5C. Fuse and antifuse regions are then patterned. In FIG. 5E, contacts 340, 350 and 360 (not shown) are formed using chemical conventional vapor deposition techniques followed by conventional planarization steps. See also U.S. Pat. No. 5,412,593, which is incorporated in its entirety herein.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A method for sensing an electrical signal from a fuse arrangement, comprising the steps of:
providing an arrangement including a fuse connected in series to an antifuse, the arrangement further including an output tap connected to a node between the fuse and the antifuse,
programming the fuse and the antifuse,
applying a sense signal across the programmed fuse and the programmed antifuse; and
measuring an output signal at the output tap.

2. The method as claimed in claim 1, said step of applying including applying a sense voltage across a combination of the programmed fuse and the programmed antifuse.

3. The method as claimed in claim 1, said step of measuring including measuring an output voltage at the output tap relative to a reference voltage.

4. The method as claimed in claim 3, said step of measuring including measuring an output voltage at the output tap relative to a ground potential.

5. The method as claimed in claim 1, said step of programming including programming the fuse prior to programming the antifuse.

6. The method as claimed in claim 1, said step of programming including programming the antifuse prior to programming the fuse.

7. The method as claimed in claim 1, said step of applying a sense signal comprising applying a sense voltage of approximately one volt.

8. The method as claimed in claim 1, said step of measuring an output signal comprising flowing a current of approximately one microamp through a sensing circuit connected to the output tap.

9. The method as claimed I claim 1, said step of programming comprising changing a resistance of the fuse to approximately one megohm, and changing a resistance of the antifuse to approximately one kilo-ohm.

10. The method as claimed in claim 1, said step of measuring comprising measuring an output voltage of approximately 0.001 volt at the output tap.

11. The method as claimed in claim 1, said step of programming comprising applying a voltage of approximately one to approximately three volts across the fuse.

12. The method as claimed in claim 1, said step of programming comprising applying a voltage of approximately two to approximately five volts across the antifuse.

13. A method for measuring an electrical signal, comprising the step of measuring an output signal at an output tap connected to a node between a programmed fuse and a programmed antifuse, the tap, node, fuse and antifuse being formed as an integrated circuit.

14. The method as claimed in claim 13, said step of measuring comprising measuring an output voltage of approximately 0.001V between the output tap and a reference potential.

15. The method as claimed in claim 14, the reference potential being ground potential.

16. A voltage measuring arrangement formed as an integrated circuit, comprising:
a fuse serially connected to an antifuse at an intermediate node, and
a voltage measuring circuit connected to said intermediate node and to a ground potential.

17. The arrangement as claimed in claim 16, further comprising a source of potential of approximately one volt connected to said fuse.
